(19) United States
(12) Patent Application Publication
(10) Pub. No.: US 2015/0228517 A1
(43) Pub. Date: Aug. 13, 2015

(54) UNIVERSAL PROCESS CARRIER FOR SUBSTRATES

(71) Applicant: Apple Inc., Cupertino, CA (US)

(72) Inventors: Howell John Chua Toc, Singapore (SG); Annabelle Q. Yang, Singapore (SG); Steven Webster, Palo Alto, CA (US)

(73) Assignee: Apple Inc., Cupertino, CA (US)

(21) Appl. No.: 14/179,777

(22) Filed: Feb. 13, 2014

(51) Int. Cl. H01L 21/673; H01L 21/683

(52) U.S. Cl. CPC H01L 21/67333; H01L 21/6835

(57) ABSTRACT

A carrier apparatus and method of assembling a carrier apparatus for processing a substrate. The carrier including a first carrier plate having a first plurality of cavities, each of the first plurality of cavities dimensioned to receive a first side of a substrate. The carrier further including a second carrier plate having a second plurality of cavities, each of the second plurality of cavities dimensioned to receive a second side of the substrate when the first carrier plate and the second carrier plate are placed in contact with one another. A magnet assembly is further provided which is configured to hold the first carrier plate and the second carrier plate together, the magnet assembly having at least one magnet positioned within a recess formed along one side of the first carrier plate or the second carrier plate.

### FIELD

An embodiment of the invention is directed to a substrate carrier for processing of substrates, more specifically, a substrate carrier held together by a magnetic force and dimensioned to expose both sides of a plurality of substrates held therein for processing. Other embodiments are also described and claimed.

### BACKGROUND

Current camera module assembly processing involves processing of singulated leadless chip carrier (LCC) substrates. Due to the substrate's near weightless characteristic and tiny size, the assembly handling process for surface-mount technology (SMT), wash and clean, flip-chip, under fill and glass attach has become challenging. Representatively, SMT and glass attach processing is done on one side of the substrate while flip-chip and under fill is done on the other side, thus a flip is required. In addition, it is difficult to hold the substrate down due to its weight and size. In particular, the substrate easily gets dislodged with vibration or air. Moreover, there is no space for, for example, use of a vacuum technique to hold the substrate in place. Conventional systems, which have tried to address these issues, include sticking a substrate to a carrier using double sided tape or mechanically clamping the substrate to a carrier. In each case, however, pick, flip and placement or transfer of the substrate from the carrier to, in some cases, another carrier, must occur after each processing step so that processing may occur on both sides of the substrate.

### SUMMARY

An embodiment of the invention is a carrier apparatus for processing a substrate. The carrier includes a first carrier plate having a first plurality of cavities, each of the first plurality of cavities dimensioned to receive a first side of a substrate. The carrier further includes a second carrier plate having a second plurality of cavities, each of the second plurality of cavities dimensioned to receive a second side of the substrate when the first carrier plate and the second carrier plate are placed in contact with one another. A magnet assembly is further provided which is configured to hold the first carrier plate and the second carrier plate together such that the substrate is held in a fixed position between the first carrier plate and the second carrier plate. The magnet assembly includes at least one magnet positioned within a recess formed along one side of the first carrier plate or the second carrier plate.

Another embodiment of the invention is microelectronic device processing apparatus including a top carrier plate having a first plurality of openings dimensioned to receive a substrate and a plurality of recesses having magnets positioned therein. The apparatus further includes a bottom carrier plate having a second plurality of openings dimensioned to receive a substrate. The bottom carrier plate further includes a material which is attracted to the magnets such that the magnets secure the top carrier plate to the bottom carrier plate when the top carrier plate is placed on the bottom carrier plate.

Another embodiment of the invention is a method of assembling a panel of substrates for processing. The method may include providing a first panel having a first set of openings and recesses having permanent magnets positioned therein. The method further includes providing a second panel having a second set of openings configured for alignment with the first set of openings and positioning a plurality of substrates between the first panel and the second panel. The first panel is magnetically attached to the second panel by the permanent magnets and opposing sides of each of the plurality of substrates are exposed through the first set of device openings and the second set of device openings.

The above summary does not include an exhaustive list of all aspects of the present invention. It is contemplated that the invention includes all systems and methods that can be practiced from all suitable combinations of the various aspects summarized above, as well as those disclosed in the Detailed Description below and particularly pointed out in the claims filed with the application. Such combinations have particular advantages not specifically recited in the above summary.

### BRIEF DESCRIPTION OF THE DRAWINGS

The embodiments are illustrated by way of example and not by way of limitation in the figures of the accompanying drawings in which like references indicate similar elements. It should be noted that references to “an” or “one” embodiment in this disclosure are not necessarily to the same embodiment, and they mean at least one.

FIG. 1 illustrates an exploded perspective view of a bottom side of a top plate of a substrate carrier and a top side of a bottom plate of the substrate carrier.

FIG. 2 illustrates a magnified view of a portion II of the top plate of the carrier of FIG. 1.

FIG. 3 illustrates a magnified view of a portion III of the bottom plate of the carrier of FIG. 1.

FIG. 4 illustrates a top plan view of the carrier of FIG. 1 with substrates positioned therein.

FIG. 5 illustrates a cross sectional view of the carrier of FIG. 4 along line 5-5.

FIG. 6 illustrates a magnified cross sectional view of a portion of the carrier of FIG. 5.

FIG. 7 is a block diagram illustrating a process of assembling a substrate carrier.

### DETAILED DESCRIPTION

In this section we shall explain several preferred embodiments of this invention with reference to the appended drawings. Whenever the shapes, relative positions and other aspects of the parts described in the embodiments are not clearly defined, the scope of the invention is not limited only to the parts shown, which are meant merely for the purpose of illustration. Also, while numerous details are set forth, it is understood that some embodiments of the invention may be practiced without these details. In other instances, well-known structures and techniques have not been shown in detail so as not to obscure the understanding of this description.

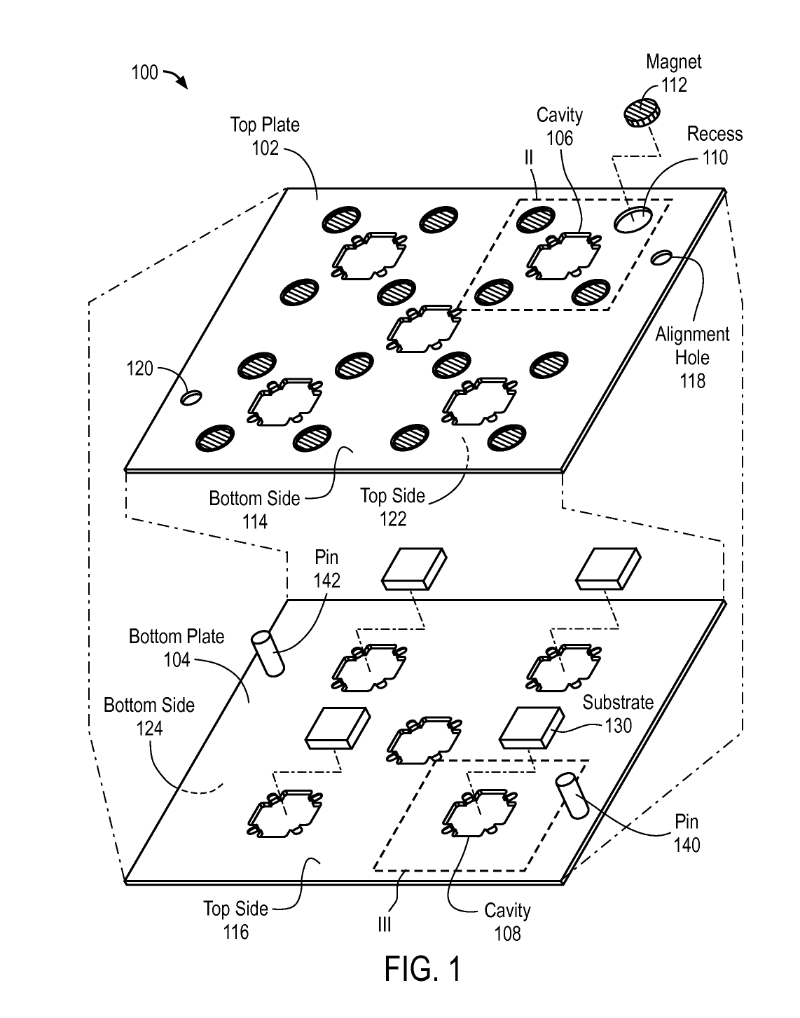

FIG. 1 is an exploded perspective view of a bottom side of a top plate of a substrate carrier and a top side of a bottom plate of the substrate carrier. From this view it can be seen that carrier 100 includes a top plate 102 and a bottom plate 104. Each of the top plate 102 and the bottom plate 104 may be substantially planar structures. In this aspect, when the top plate 102 is positioned on the bottom plate 104, the top plate 102 is entirely within one plane and the bottom plate 104 is entirely within another different plane. In addition, top plate 102 and bottom plate 104 may have substantially the same footprint as shown in FIG. 1. In other words, an overall size and shape of the top plate 102 and the bottom plate 104 is substantially the same. Top plate 102 and bottom plate 104 may be made of any material that allows top plate 102 and bottom plate 104 to be held together using a magnetic force. Representatively, top plate 102 and bottom plate 104 may be made of a metallic material, for example, a ferromagnetic metallic material or, more specifically, a metal alloy such as stainless steel. Top plate 102 and/or bottom plate 104 may be integrally formed from the metallic material such that the plates, as well as any features formed therein, are inseparable parts of a single integrally formed structure.

The top plate 102 may include cavities 106 and bottom plate 104 may include cavities 108, which are dimensioned to receive opposing sides of a substrate 130 and fixedly secure substrate 108 within carrier 100 when top plate 102 is positioned on bottom plate 104. The substrate 130 may be, for example, a substrate to which a microelectronic device can be mounted, also referred to herein as a microelectronic device substrate. For example, in some embodiments, the substrate 130 is a ceramic substrate such as a leadless chip carrier (LCC) substrate or other similarly sized substrate that may be subjected to similar substrate processing techniques (e.g. SMT, ultrasonic flip-chip mounting, wash and clean, flip-chip, under fill and glass attach or ultrasonic mounting). In some embodiments, the substrate 130 may be a substrate subjected to a camera module assembly process. It is further contemplated that the substrate 130 may be any other type of micro scale structure or device that could benefit from being able to be processed as a panel of substrates as described herein. Each of cavities 106 and cavities 108 may have substantially the same dimensions such that they are substantially mirror images of one another. It is further to be understood that although five cavities 106 and five cavities 108 are illustrated within each of the top plate 102 and bottom plate 104, respectively, it is contemplated that any number of cavities suitable for holding a desired number of substrates may be included. For example, in some embodiments, as many as 20 cavities 106 and 20 cavities 108, or more, may be formed within each of plates 102, 104, respectively. In addition, a pattern of cavities 106 and cavities 108 within top plate 102 and bottom plate 104, respectively, may be substantially the same such that when top plate 102 is positioned on bottom plate 104, each of cavities 106 align with cavities 108. For example, in one embodiment, each of cavities 106 in one row may be slightly offset from the cavities in the next row down such that every other row of cavities in top plate 102 is aligned with the other. Cavities 108 may have a similar pattern. Other patterns, however, are contemplated, for example, each of the cavities in each row may be directly aligned one on top of the other.

Top plate 102 may further include recesses 110 formed within a bottom side 114. Recesses 110 are dimensioned to receive magnets 112. Although cylindrically shaped recesses 110 are illustrated in FIG. 1, it is contemplated that recesses 110 may have any size and shape suitable for receiving magnets 112. For example, in embodiments where magnets 112 are cylindrical, recesses 110 have a corresponding cylindrical shape, however, where magnets 112 are cubes, or have another shape, recesses 110 have a cube shape, or other shape. Magnets 112 may be secured within recesses 110 according to any suitable attachment mechanism. For example, in one embodiment, magnets 112 are secured within recesses 110 using an adhesive transfer tape. Magnets 112 may be, in one embodiment, any type of permanent magnet capable of generating a magnetic force sufficient to pull and secure bottom plate 104 to top plate 102. Representatively, in one embodiment, magnets 112 are samarium-cobalt magnets. In addition, although sixteen recesses 110 and sixteen magnets 112 are illustrated, it is contemplated that any number of recesses 110 and magnets 112 suitable for securing bottom plate 104 to top plate 102 may be used. For example, the number of recesses 110 may be dependent upon the number of magnets 112 needed, and the number of magnets 112 needed may be dependent upon the strength of the magnets (i.e. fewer magnets are needed in the case of relatively strong magnets, whereas more magnets may be needed in the case of relatively weak magnets). In addition, in some embodiments, four recesses 110 may be formed around each of cavities 106 such that four magnets 112 are positioned around each of cavities 106. It is to be understood, however, that in some embodiments more or less recesses 110 may be formed near each of cavities 106 depending upon the strength of magnets 112 as previously discussed.

In some embodiments, top plate 102 may further include one or more of alignment holes 118, 120 to facilitate alignment and release of top plate 102 from bottom plate 104. Alignment holes 118, 120 may be dimensioned to receive pins 140, 142, respectively, extending from the top side 116 of bottom plate 104. Although alignment holes 118, 120 are shown formed in top plate 102, it is further contemplated that in some embodiments, alignment holes may be formed in bottom plate 104 and alignment pins may instead extend from top plate 102. In still further embodiments, alignment holes 118, 120 may be omitted and another alignment mechanism may be used to align top plate 102 with bottom plate 104, for example, complimentary recesses, grooves or the like.

A panel of substrates may be formed by carrier 100 by, for example, positioning one side of a substrate 130 within each of cavities 108 of bottom plate 104 and then placing top plate 102 over bottom plate 104 such that the opposing side of the substrate 130 is aligned with a respective one of cavities 106. More specifically, bottom side 114 of top plate 102 is placed on top side 116 of bottom plate 104 such that an outer surface of carrier 100 is formed by the top side 122 of top plate 102 and the bottom side 124 of bottom plate 104. Each of cavities 106 and cavities 108 are aligned with one another. The substrates 130 are positioned between top plate 102 and bottom plate 104 within aligned cavities 106, 108. Magnets 112 generate a magnetic force that secures the top plate 102 to bottom plate 104, and in turn, the substrates 130 are secured within their respective cavities 106, 108 between top plate 102 and bottom plate 104. Such a configuration in which the substrates are secured between magnetically attached plates, as opposed to mechanically attached plates, provides several advantages.

Representatively, the additional handling steps that may be required to mechanically attach the plates together using, for example, a clamping or bracket assembly, are omitted. In addition, each of magnets 112 may have the same strength such that an attachment force is evenly and consistently distributed along the plates.

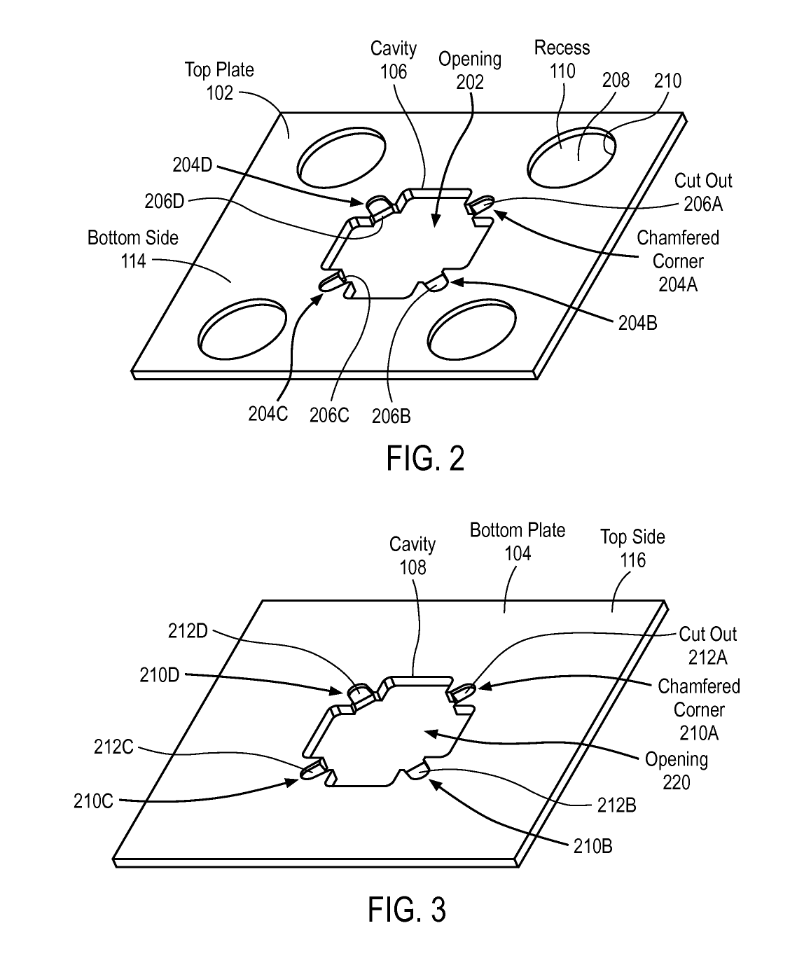

The specific dimensions of cavities 106 and recesses 110 within top plate 102 will now be described in more detail in reference to FIG. 2. In particular, FIG. 2 illustrates a magnified view of portion II, illustrated with dashed lines, of the top plate of the carrier of FIG. 1. Magnets 112 and substrates 130 are not shown so that features of recesses 110 and cavities 106 can be seen more clearly. From this view, it can be seen that cavity 106 includes an opening 202 and chamfered corners 204A-204D. Opening 202 is formed entirely through top plate 102 and has similar dimensions to the substrate it is designed to receive such that a maximum surface area of the substrate is exposed through the opening 202. For example, in the illustrated embodiment, opening has a substantially square shaped profile. Each of chamfered corners 204A-204D are dimensioned to overlap corners of the substrate 130 so that the substrate 130 cannot pass through the opening 202. Chamfered corners 204A-204D may further include cut outs 206A-206D, respectively. Cut outs 206A-206D are cutout regions within a thickness of the chamfered corners 204A-204D. Cut outs 206A-206D may have any size and dimensions suitable for receiving corners of a substrate. For example, cut outs 206A-206D may form D shaped recessed regions. When the substrate 130 is positioned within opening 202, the corners rest within cut outs 206A-206D. In this aspect, each of cut outs 206A-206D may have a depth of about half a thickness or more of the substrate positioned therein such that only about half or less of the opposing side of the substrate extends outside of the plane of top plate 102. It should be understood that although opening 202 is illustrated as having four chamfered corners 204A-204D, each with cut outs 206A-206D, any number of chamfered corners 204A-204D and cut outs 206A-206D sufficient to hold a substrate within cavity 106 may be provided. Representatively, in one embodiment, only two diametrically opposed corners of cavity 106 may include chamfered corners and cutouts.

As can further be seen from FIG. 2, recess 110 is cut into the bottom side 114 of top plate 102. In this aspect, recess 110 includes a solid base portion 208 and side wall 210 extending substantially perpendicular to base portion 208. Side wall 210 may have a length less than that of a thickness of top plate 102 such that the depth of recess 110 is less than the thickness of top plate 102 and recess 110 does not extend entirely through top plate 102. Rather, recess 110 can be deep enough to mount a magnet flush with bottom side 114 without exposing the magnet through the top side 122. For example, a depth of recess 110 (i.e. a length of sidewall 210) may be substantially the same as a thickness of the magnet positioned therein. Although the dimensions of a single recess 110 and cavity 106 are described in reference to FIG. 2, it is contemplated that each of the cavities 106 found in top plate 102 may have the same dimensions and each of the recesses 110 found in top plate 102 may have the same dimensions. Alternatively, recesses 110 and cavities 106 may have different dimensions where magnets and/or substrates, respectively, of different sizes and shapes are to be coupled to top plate 102.

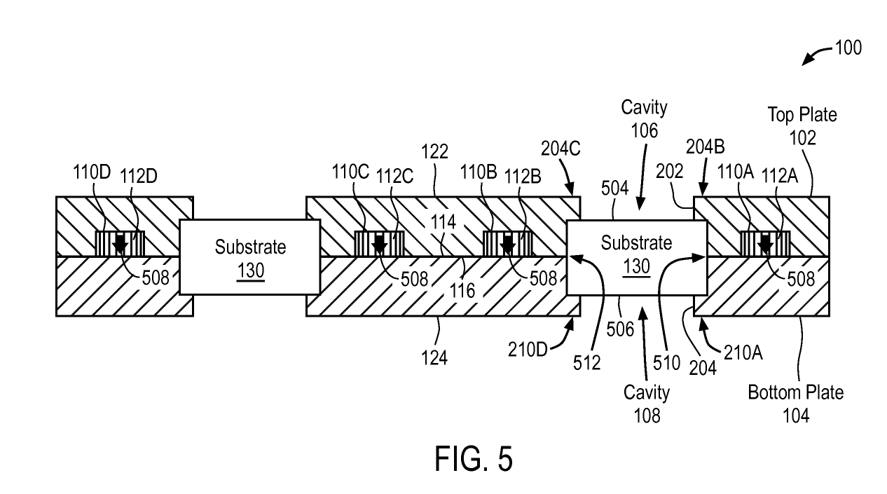

FIG. 3 illustrates a magnified view of portion III, illustrated with dashed lines, of the bottom plate of the carrier of FIG. 1. It should be understood that cavity 108 is being viewed in FIG. 3 from top side 116 of bottom plate 104. From this view, it can be seen that cavity 108 is substantially similar to cavity 106. Representatively, cavity 108 includes an opening 220 formed entirely through bottom plate 104 and chamfered corners 210A-210D. Opening 220 has similar dimensions to the substrate it is designed to receive such that a maximum surface area of the substrate is exposed through the opening 220. For example, in the illustrated embodiment, opening has a substantially square shaped profile. Each of chamfered corners 210A-210D are dimensioned to overlap corners of the substrate 130 so that the substrate 130 cannot pass through the opening 220. Chamfered corners 210A-210D may further include cut outs 212A-212D, respectively. Cut outs 212A-212D are cutout regions within a thickness of the chamfered corners 210A-210D. Cut outs 212A-212D may have similar shapes and sizes as cut outs 206A-206D. Representatively, cut outs 212A-212D may have any size and dimensions suitable for receiving corners of a substrate. For example, cut outs 212A-212D may form D shaped recessed regions. When the substrate 130 is positioned within opening 220, the corners rest within cut outs 212A-212D. In this aspect, when the bottom side 114 of top plate 102 is placed on the top side 116 of bottom plate 104, cut outs 206A-206D and cut outs 212A-212D are aligned to form pockets (see FIG. 5) within which the substrate 130 corners can be positioned. Each of cut out regions 206A-206D and 212A-212D may be of a depth which is about half the thickness of the substrate 130 such that the bottom side 114 of top plate 102 and top side 116 of bottom plate 104 are flush with one another when substrate 130 is positioned between plates 102 and plate 104.

It should be understood that although opening 220 is illustrated as having four chamfered corners 210A-210D, each with cut outs 212A-212D, any number of chamfered corners 210A-210D and cut outs 212A-212D sufficient to hold a substate within cavity 108 may be provided. Representatively, in one embodiment, only two diametrically opposed corners of cavity 108 may include chamfered corners and cutouts. In addition, where top plate 102 also includes cavity 106 with only two chamfered corners and cutouts as previously discussed, the chamfered corners and cutouts of cavity 106 may be on different corners than that of cavity 108 such that when the substrate 130 is between cavity 106 and cavity 108, each of its corners are held between top plate 102 and bottom plate 104.

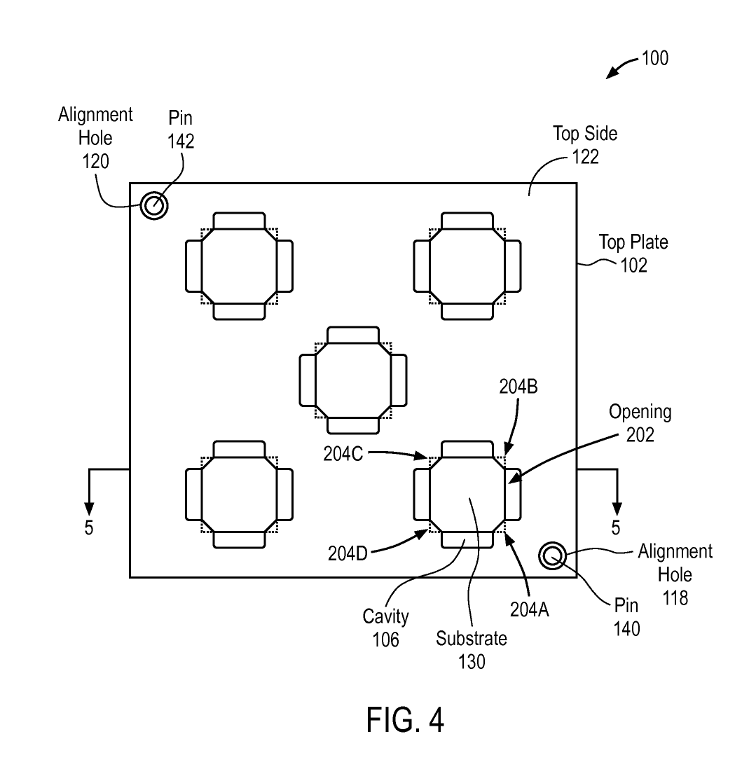

FIG. 4 illustrates a top plan view of the carrier of FIG. 1 with substrates positioned therein. From this view, it can be seen that when substrate 130 is positioned within cavity 106, only chamfered corners 204A-204D of cavity 106 overlap corners of substrate 130. Similarly, although not shown, chamfered corners 210A-210D of bottom plate 104 overlap the bottom side of the substrate corners. The rest of substrate 130 is exposed through opening 202 (and opening 220 in bottom plate 104). In addition, pins 140, 142 which extend from the top side 116 of bottom plate 104 are shown positioned through alignment holes 118, 120, respectively, to facilitate alignment of top plate 102 with bottom plate 104.

FIG. 5 illustrates a cross sectional view of the carrier of FIG. 4 along line 5-5. From this view, the positioning of substrates 130 between top plate 102 and bottom plate 104 can be more clearly seen. In particular, from this view, it can be seen that carrier 100 is assembled by positioning bottom side 114 of top plate 102 on top side 116 of bottom plate 104. A top side 122 of top plate 102 and bottom side 124 of bottom plate 124 therefore form the outer surfaces of carrier 100. Substrate 130 is held within cavity 106 of top plate 102 and cavity 108 of bottom plate 104 along its corners within pockets 510, 512 formed by chamfered corners 204B and 204C of top plate 102 and chamfered corners 210A and 210D of bottom plate 104. It is further to be understood that, although not shown in this view, the remaining corners of substrate 130 are positioned within pockets formed by chamfered corners 204A and 204D of top plate 102 and chamfered corners 210B and 210C of bottom plate 104.

Magnets 112A-112D are positioned within recesses 110A-110D formed along the bottom side 114 of top plate 102. Magnets 112A-112D generate a magnetic field which produces an attractive force with bottom plate 104 as illustrated by arrows 508. This attractive force 508 secures top plate 102 to bottom plate 104, and in turn, substrates 130 between top plate 102 and bottom plate 104. Since substrates 130 are positioned within open cavities 106, 108 of each of top plate 102 and bottom plate 104, respectively, opposing sides 504 and 506 of substrate 130 are exposed. In addition, since both sides of substrate 130 are exposed, both sides may be processed by subsequent processing operations (e.g. SMT, wash and clean, flip-chip, under fill and glass attach) without the need for pick, flip or removal of substrate 130 from carrier 100. Moreover, since a plurality of cavities are formed within carrier 100, several substrates may be processed simultaneously.

It should also be understood that in some embodiments, recesses 110A-110D and magnets 112A-112D are positioned only within one side of carrier 100, for example, top plate 102. In addition, each of magnets 112A-112D may be positioned such that an orientation of each of the magnetic poles of magnets 112A-112D is the same. In other words, the South pole (S) of each of magnets 112A-112D may face away from top plate 102 (toward bottom plate 104) as shown, or the North pole (N) may face away from top plate 102 (toward bottom plate 104). The orientation of the poles may depend, for example, on the pole that a magnetic material of bottom plate 104 is attracted to. In particular, as previously discussed, bottom plate 104 does not include magnets, but rather, a magnetic material. Thus, it is important that magnets 112A-112D are oriented in such a manner that they generate an attractive force with the magnetic material of bottom plate 104.

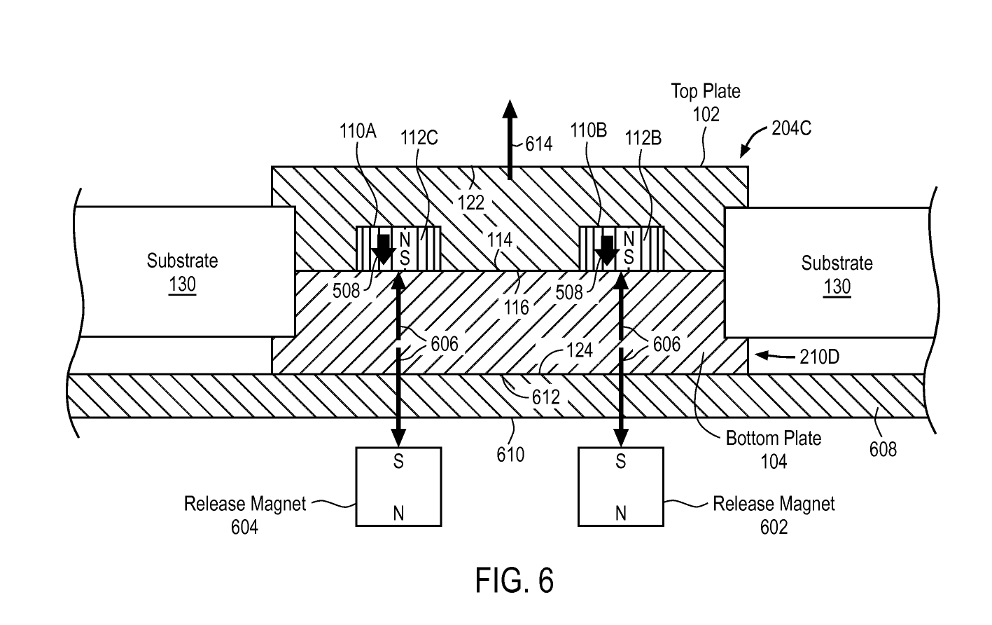

Generation of a magnetic force from only one of the plates, as opposed to positioning magnets on both top plate 102 and bottom plate 104, provides an attractive force sufficient to hold top plate 102 and bottom plate 104 together during processing while still allowing them to be separated from one another using, for example, non-mechanical forces when necessary. For example, in one embodiment, top plate 102 and bottom plate 104 are separated using a repelling magnetic force as discussed in more detail in reference to FIG. 6.

In particular, FIG. 6 illustrates a magnified cross sectional view of a portion of the carrier of FIG. 5 and a release magnet assembly which generates a magnetic field capable of releasing top plate 102 from bottom plate 104. Representatively, in one embodiment, release magnets 602, 604 may be permanent magnets that generate a magnetic field. Release magnets 602, 604 may be oriented with respect to magnets 112B and 112C such that the magnetic field generates a repelling force, as illustrated by arrows 606, between them. For example, in the case where magnets 112A and 112B have their South poles facing toward bottom plate 104 (away from top plate 102), release magnets 602, 604 may be positioned along a bottom side 124 of bottom plate 104 with their South poles facing magnets 112A and 112B (facing top plate 102). Alternatively, where magnets 112A and 112B have their North poles facing bottom plate 104 (away from top plate 102), release magnets 602, 604 may be positioned along a bottom side 124 of bottom plate 104 with their North poles facing magnets 112A and 112B (facing top plate 102). This repelling force 606 is at least as strong as, and in some cases stronger than, attractive force 508 and therefore cancels out, or overrides, attractive force 508. Since attractive force 508 is no longer strong enough to secure top plate 102 to bottom plate 104, top plate 102 (having magnets 112A and 112B attached thereto) is pushed away, or released from, bottom plate 104 in a direction of arrow 614.

In some cases, release of top plate 102 from bottom plate 104 is facilitated by mounting bottom plate 104 to a plate support member 608 such that top plate 102 can be removed while bottom plate 104 remains fixed. Bottom plate 104 may be mounted to plate support member 608 according to any suitable mounting mechanism. For example, in one embodiment, clamps may be used to clamp bottom plate 104 to plate support member 608. In some cases, depending upon a thickness of the clamps, recesses may further be formed around a perimeter of top plate 102 such that top plate 102 fits around the clamps. Where plate support member 608 is present, release magnets 602, 604 are positioned along a bottom side 610 of plate support member 608 and bottom plate 104 is positioned along a top side 612 of plate support member 608 such that the repelling force 606 passes through both plate support member 608 and bottom plate 104.

It is further contemplated that although in the illustrated embodiment, a repelling magnetic force 606 is used to release top plate 102 from bottom plate 104, in some cases an attractive magnetic force may be used. For example, release magnets 602, 604 may be positioned along top side 122 of top plate 102 with an opposite polarity to that of magnets 112B, 112C facing top plate 102. In this aspect, magnets 112B, 112C and in turn, top plate 102, are attracted to release magnets 602, 604. This attractive force draws top plate 102 away from bottom plate 104 and allows it to be removed.

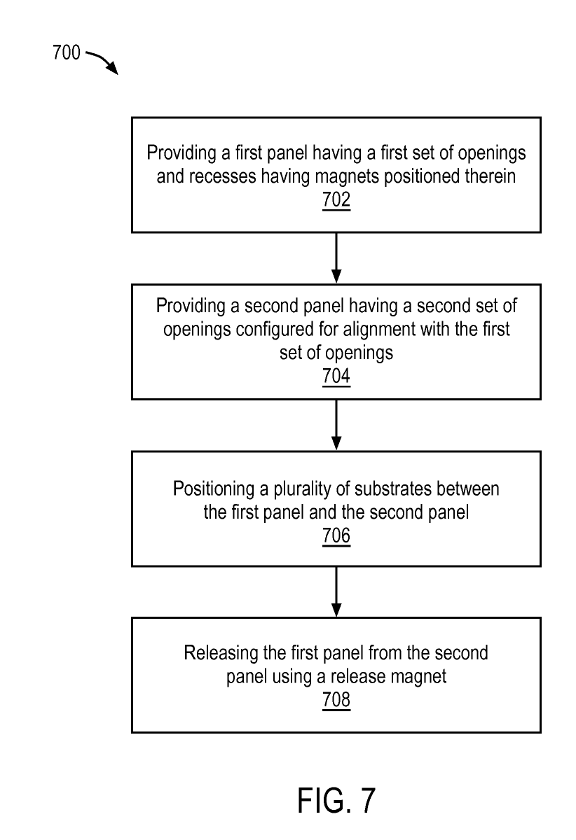

FIG. 7 is a block diagram illustrating one embodiment of a process of assembling a substrate carrier. Representatively, in one embodiment, process 700 includes providing a first plate or panel having a first set of openings and recesses having magnets positioned therein (block 702). The first plate or panel may be, for example, top plate 102 described in reference to FIG. 1. Process 700 may further include providing a second plate or panel having a second set of openings configured for alignment with the first set of openings (block 704). The second plate or panel may be, for example, bottom plate 104 described in reference to FIG. 1. Substrates may be positioned between the first panel and the second panel to complete the carrier assembly (block 706). The substrates may be positioned within the aligned device openings such that both sides of the substrates are exposed for processing. Moreover, the second panel may include a magnetic material such that the first panel and the second panel are magnetically held together using the magnets found in the first panel. To release the first panel from the second panel, a release magnet, which generates a magnetic field that repels the magnetic field of the magnets in the first panel, may be used (block 708).

While certain embodiments have been described and shown in the accompanying drawings, it is to be understood that such embodiments are merely illustrative of and not restrictive on the broad invention, and that the invention is not limited to the specific constructions and arrangements shown and described, since various other modifications may occur to those of ordinary skill in the art. For example, in some embodiments, both sides of the carrier (e.g. the top plate and the bottom plate) may have magnets mounted therein. The description is thus to be regarded as illustrative instead of limiting.

What is claimed is:

1. A carrier apparatus for processing a substrate comprising:
a first carrier plate having a first plurality of cavities, each of the first plurality of cavities dimensioned to receive a first side of a substrate;
a second carrier plate having a second plurality of cavities, each of the second plurality of cavities dimensioned to receive a second side of the substrate when the first carrier plate and the second carrier plate are placed in contact with one another; and
a magnet assembly configured to hold the first carrier plate and the second carrier plate together such that the substrate is held in a position between the first carrier plate and the second carrier plate, the magnet assembly having at least one magnet positioned within a recess formed along one side of the first carrier plate or the second carrier plate.

2. The apparatus of claim 1 wherein only the first carrier plate comprises the magnet assembly and the second carrier plate is made of a metallic material that is attracted to the at least one magnet of the magnet assembly.

3. The apparatus of claim 1 wherein the substrate is a microelectronic device substrate.

4. The apparatus of claim 1 wherein the first plurality of cavities and the second plurality of cavities have chamfered corners.

5. The apparatus of claim 1 wherein each of the first plurality of cavities and the second plurality of cavities form openings such that both the first side and the second side of the substrate are exposed through the openings.

6. The apparatus of claim 1 wherein a footprint of the first carrier plate is substantially the same as a footprint of the second carrier plate.

7. The apparatus of claim 1 further comprising:
a release magnet assembly configured to release the first carrier plate from the second carrier plate.

8. A microelectronic device substrate processing apparatus comprising:
a top carrier plate having a first plurality of openings dimensioned to receive a microelectronic device substrate and a plurality of recesses having magnets positioned therein; and
a bottom carrier plate having a second plurality of openings dimensioned to receive a microelectronic device substrate, wherein the bottom carrier plate comprises a material which is attracted to the magnets such that the magnets secure the top carrier plate to the bottom carrier plate when the top carrier plate is placed on the bottom carrier plate.

9. The apparatus of claim 8 wherein an orientation of each of the poles of the magnets within the recesses is the same.

10. The apparatus of claim 8 wherein each of the first plurality of openings and the second plurality of openings are inseparable within their respective top carrier plate and bottom carrier plate.

11. The apparatus of claim 8 wherein each of the top carrier plate and the bottom carrier plate are single integrally formed plates.

12. The apparatus of claim 8 further comprising:
a release magnet assembly comprising at least one release magnet having a same polarity as the magnets of the top carrier plate such that positioning the release magnet assembly near the top carrier plate releases the top carrier plate from the bottom carrier plate when the top carrier plate is placed on the bottom carrier plate.

13. The apparatus of claim 8 wherein each of the first plurality of openings and the second plurality of openings have chamfered corners which overlap corners of a microelectronic device substrate positioned therein.

14. The apparatus of claim 8 wherein a pattern of the first plurality of openings is substantially similar to a pattern of the second plurality of openings such that the first plurality of openings are aligned with the second plurality of openings when the top carrier plate is placed on the bottom carrier plate.

15. The apparatus of claim 8 wherein the material of the bottom carrier plate is a ferromagnetic material.

16. A method of assembling a panel of substrates for processing comprising:
providing a first panel having a first set of openings and recesses having permanent magnets positioned therein;
providing a second panel having a second set of openings configured for alignment with the first set of openings; and
positioning a plurality of substrates between the first panel and the second panel, wherein the first panel is magnetically attached to the second panel by the permanent magnets and opposing sides of each of the plurality of substrates are exposed through the first set of openings and the second set of openings.

17. The method of claim 16 further comprising:
releasing the first panel from the second panel using a release magnet.

18. The method of claim 16 wherein a same polarity of each of the permanent magnets of the first panel faces away from the first panel.

19. The method of claim 17 wherein the release magnet generates a repelling magnetic force greater than an attractive force between the permanent magnets and the second panel.

20. The method of claim 17 further comprising:
fixedly attaching the second panel to a panel support member such that when the release magnet is used to release the first panel from the second panel, the second panel remains in the fixed position.
